(19) United States
(12) Patent Application Publication
(10) Pub. No.: US 2014/0159825 A1
(43) Pub. Date: Jun. 12, 2014

(54) VOLTAGE CONTROLLED OSCILLATOR WITH LOW PHASE NOISE AND HIGH Q INDUCTIVE DEGENERATION

(71) Applicant: Texas Instruments Incorporated, Dallas, TX (US)

(72) Inventors: Sreekiran Samala, Richardson, TX (US); Vijay Rentala, Plano, TX (US)

(21) Appl. No.: 14/102,125

(22) Filed: Dec. 10, 2013

Related U.S. Application Data
(60) Provisional application No. 61/735,193, filed on Dec. 10, 2012.

(51) Int. Cl. H03B 5/18

(52) U.S. Cl. CPC H03B 5/1847
USPC 331/117 R

(57) ABSTRACT

A voltage controlled oscillator (VCO) includes an LC tank circuit coupled between a supply terminal, a first node and a second node. A pair of cross coupled transistors is coupled to the first node and the second node. A degeneration inductor, center tapped to a ground terminal, is coupled to the pair of cross coupled transistors configured to inductively degenerate each of the pair of cross coupled transistors and configured to resonate a source capacitance of each of the pair of cross coupled transistors. The VCO is configured to be having a low phase noise with high quality factor using inductive degeneration.

### CROSS REFERENCE TO RELATED APPLICATIONS

This non-provisional application claims the benefit of U.S. Provisional Patent Application No. 61/735,193, filed on Dec. 10, 2012, which is incorporated herein by reference in its entirety.

### TECHNICAL FIELD

Embodiments of the disclosure relate to voltage controlled oscillators in integrated circuits.

### BACKGROUND

In wireless communication systems there is an increased the demand for low-cost and low power consumption with high spectral efficiencies that in turn demands intense activity in the RF (radio frequency) systems of the wireless communication systems. One of the main blocks that is researched is such systems is the frequency synthesizer, usually based on voltage controlled oscillators (VCOs). The RF systems in today's wireless communication systems require the VCO to have a phase noise figure better than −120 dBc/Hz at 1 MHz from a 20G carrier. This is an extremely tight phase noise specification.

Due to the ease of implementation and minimum number of noise sources leading to good phase noise basic performances in the CMOS process, LC oscillators with differential and cross coupled topology are among the most preferred. However, in such cross coupled topologies, the phase noise is dominated by the noise of the cross coupled components (pair of cross coupled transistors) that includes thermal noise and flicker noise. Flicker noise getting up-converted due to nonlinearities in the pair of cross coupled transistors at high oscillation swings of the VCO is a big problem.

### SUMMARY

This Summary is provided to comply with 37 C.F.R. §1.73, requiring a summary of the invention briefly indicating the nature and substance of the invention. It is submitted with the understanding that it will not be used to interpret or limit the scope or meaning of the claims.

An embodiment provides a voltage controlled oscillator (VCO) that includes an LC tank circuit coupled between a supply terminal, a first node and a second node. A pair of cross coupled transistors is coupled to the first node and the second node. A degeneration inductor is coupled to the pair of cross coupled transistors, configured to inductively degenerate each of the pair of cross coupled transistors and configured to resonate a source capacitance of each of the pair of cross coupled transistors. The VCO is configured to be of a low phase noise with high quality factor inductive degeneration.

Another embodiment provides an integrated circuit that includes a VCO coupled to an electronic circuit. The VCO includes an LC tank circuit coupled between a supply terminal, a first node and a second node. A pair of cross coupled transistors is coupled to the first node and the second node. A degeneration inductor is coupled to the pair of cross coupled transistors, configured to inductively degenerate each of the pair of cross coupled transistors and configured to resonate a source capacitance of each of the pair of cross coupled transistors. The VCO is configured to be of a low phase noise with high quality factor inductive degeneration.

Other aspects and example embodiments are provided in the Drawings and the Detailed Description that follows.

### BRIEF DESCRIPTION OF THE VIEWS OF DRAWINGS

FIG. 1 is a circuit diagram of a voltage control oscillator (VCO);

FIG. 2 is another circuit diagram of a VCO;

FIG. 3 is a circuit diagram of a VCO according to an embodiment;

FIG. 4 is a graphical illustration of the oscillator waveforms of the VCO of FIG. 3;

FIG. 5 is a layout implementation of the VCO according to an embodiment; and

FIG. 6 is another layout implementation of the VCO according to an embodiment.

### DETAILED DESCRIPTION OF THE EMBODIMENTS

A voltage controlled oscillator (VCO) is a fundamental building block in a transceiver system. It provides a local oscillation (LO) signal source for a mixer that translates an intermediate frequency (IF) to a radio frequency (RF), or vice versa. FIG. 1 illustrates a circuit implementation of a VCO that has a cross coupled topology. The VCO includes an LC tank circuit having a center tapped inductor 110 coupled in parallel with a variable capacitor 115. The LC tank circuit is coupled to the supply voltage terminal through a resistor. The LC tank, having the inductor 110 in parallel with the variable capacitor 115, forms a resonant circuit that determines the frequency of the VCO. The LC tank is coupled to a pair of cross coupled re-channel transistors 120. The drains of the transistors 120 are cross coupled to the opposite gates. A CMOS implementation is preferred since no coupling devices are required to connect the two drains to the opposite gates, thus simplifying the circuit topology to a bipolar implementation. The drains of the transistors 120 are coupled to the variable capacitor 115. The pair of cross coupled transistors 120 is used to compensate for the losses in the variable capacitor 115 and the inductor 110. The pair of cross coupled transistors 120 creates negative impedance that compensate for the losses. The output voltage is available at the drains of the transistors 120 and to keep best waveform symmetry and efficiency, it is drawn in a differential way through suitable followers. An inductor 125 is coupled to the sources of the pair of cross coupled transistors 120 and to a ground terminal. The resistor 105 determines the bias current in the two transistors of the cross coupled pair which in turn determine the oscillation amplitude of the VCO. The inductor 125 is used to filter out the bias current noise due to the resistor 105, using 2f0 filtering technique. Since the pair of cross coupled transistors 120 is not degenerated, it has worse flicker noise (1/f noise). Further, since the nonlinearity of the pair of cross coupled pair of transistors 120 is high, it leads to worse up-conversion of the flicker noise at high oscillation swings in the VCO. At high oscillation swings the pair of cross coupled transistors 120 becomes nonlinear at crossover that leads to worse up-conversion of the flicker noise. Further, the VCO implementations such as in FIG. 1 have worse quality factor (Q) and it is also sensitive to ground inductance.

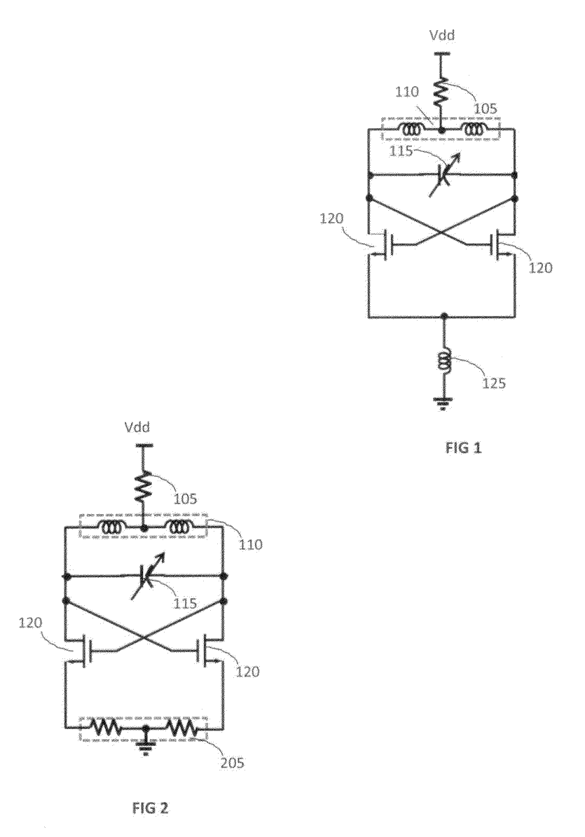

One way to overcome the noise limitations of the VCO of FIG. 1 is to have a VCO with a pair cross coupled transistors 120 with resistive degeneration, meaning degenerating each of the pair of cross coupled transistors 120 using a resistor. The inductor 125 of the VCO of FIG. 1 is replaced with a center tapped resistor 205 that is coupled to the sources of the pair of cross coupled transistors 120 and to the ground in FIG. 2. All the other circuit components are same in connection and operation and are not repeated for the sake of simplicity.

However, it is noted that even with resistive degeneration, the degeneration of the pair of crossed coupled transistors of FIG. 2 is minimum due to available head room, which means that there is limited flicker noise suppression. Further, since the nonlinearity of the cross coupled pair of transistors 120 is high; it leads to worse up-conversion of the flicker noise at high oscillation swings in the VCO. For example, in the implementation of FIG. 2, phase noise was calculated at −115 dBc/Hz at 1 MHz offset for 7.5 GHz center frequency. It is also noted that the phase noise of the VCO in FIG. 2, was dominated by the noise of the cross coupled pair of transistors 120 (thermal noise and flicker noise).

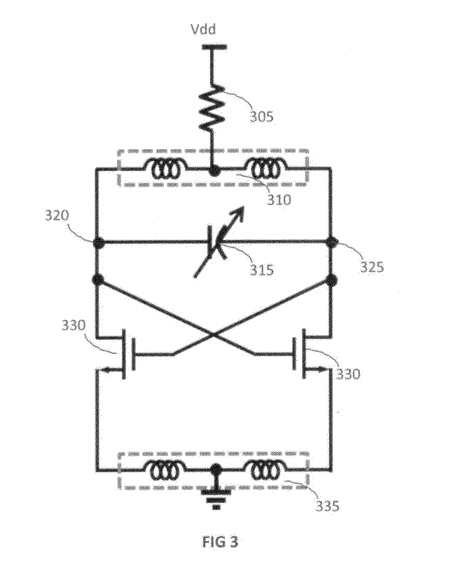

FIG. 3 illustrates a circuit implementation of a VCO that uses inductive degeneration with high quality factor (Q) that overcomes the disadvantages of the VCOs illustrated in FIGS. 1 and 2. The VCO includes an LC tank circuit having a center tapped inductor 310 coupled in parallel with a variable capacitor 315. The LC tank circuit having the inductor 310 in parallel with the variable capacitor 315 forms a resonant circuit that determines the frequency of the VCO. The LC tank circuit is coupled between a supply terminal (Vdd), a first node 320 and a second node 325. The LC tank circuit is coupled to the supply terminal through a resistor 305. The LC tank circuit provides inductance between the supply terminal and the first node 320 and the supply terminal the second node 325, and for providing capacitance between the first node 320 and the second node 325. A pair of cross coupled transistors 330, implemented as n-channel transistors, is coupled to the nodes 320 and 325. The drains of the transistors 330 are cross coupled to the opposite gates. The drains of the transistors 330 are coupled to the variable capacitor 315 through the nodes 320 and 325. The pair of cross coupled transistors 330 is used to compensate for the losses in the variable capacitor 315 and the inductor 310. The pair of cross coupled transistors 330 creates negative impedance that compensate for the losses. The output voltage of the VCO is available at the drains of the transistors 330 and to keep best waveform symmetry and efficiency, it is drawn in a differential way via suitable followers. In implementation, a pair of capacitors are coupled between the nodes 320 and 325 and the ground terminal from which the output voltages are available.

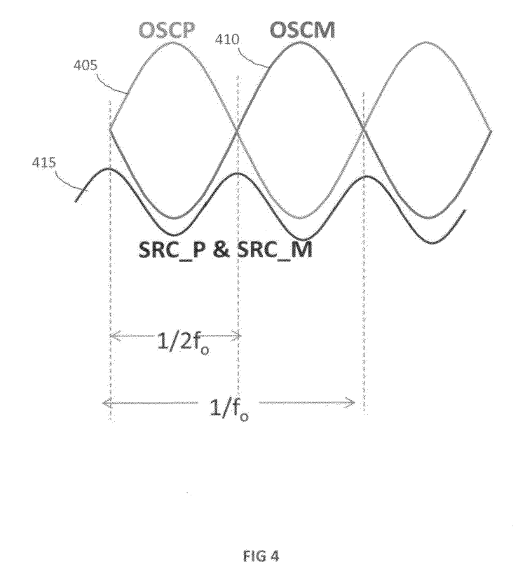

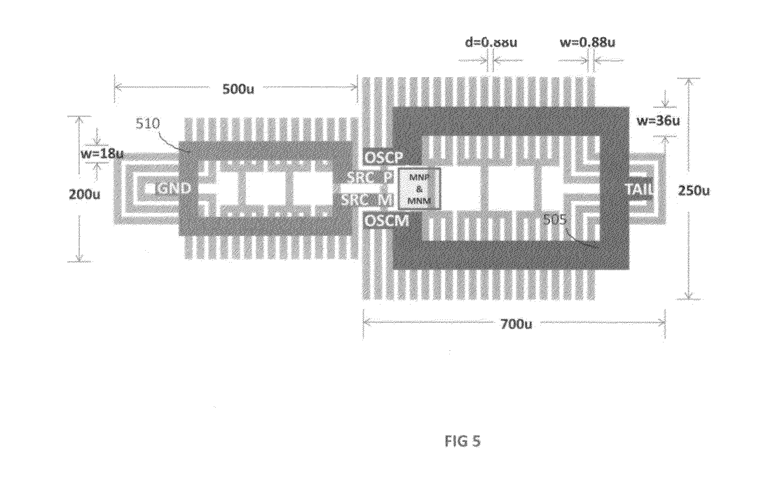

A degeneration inductor 335 is coupled to the pair of cross coupled transistors 330 and to the ground terminal. In an embodiment, the degeneration inductor 335 is center tapped to the ground terminal thus configured to degenerate the pair of cross coupled transistors 330. The degeneration inductor 335 is configured to linearize a gain of the pair of cross coupled transistors 330 such that there is low flicker noise up-conversion at high oscillation swings in the VCO. The degeneration inductor is configured to minimize a Vgs (gate to source voltage) of the cross coupled pair of transistors at crossover of a differential outputs of the VCO. At crossover of the VCO differential outputs, the Vgs of the pair of cross coupled transistors goes to minimum which is further illustrated in FIG. 4. Sensitivity of the VCO to thermal and flicker noise in the pair of cross coupled transistors 330 is also reduced. In one embodiment, the implementation is in such a way that the degeneration inductor 335 is configured not to degrade a quality factor of the LC tank circuit at high oscillation swings, by providing a high impedance path to ground when any one of the pair of cross coupled transistors enter triode region due to high oscillation swings. It is noted that the VCO of FIG. 3 is insensitive to ground inductance at the center tap of the degeneration inductor 335. Further, in one embodiment, the VCO can be used even with low Q inductors to improve the phase noise.

FIG. 4 graphically illustrates how the Vgs of the pair of cross coupled transistors is minimized. As shown in FIG. 4, OSCP (405) & OSCM (410) are the nodes 320 and 325 of the VCO. OSCP and OSCM have a differential voltage swing at fo, where fo is the frequency of oscillation. SRC_P and SRC_M, 415 are the sources of the pair of cross coupled transistors 330 across which the degeneration inductor 335 forms another resonant tank with the effective capacitance at those two nodes 320 and 325. The resonant frequency of degeneration inductor 335 and the source capacitance of the pair of cross coupled transistors 330 is at 2*fo as depicted in FIG. 4. At cross over of the differential outputs the voltage of SRC_P and SRC_M is at a maximum. This minimizes the Vgs of the pair of cross coupled transistors 330 at the cross over instants. The crossover time instants are the most sensitive points for noise injection form the pair of cross coupled transistors 330. Since the Vgs of the pair of cross coupled transistors 330 is minimized at the cross over instants, noise injection reduces and thus the phase noise reduces. The maxima of SRC_P and SRC_M or the minima of Vgs of the pair of cross coupled transistors 330 at the cross over instants depend on the Q of degeneration inductor 335. Since a high Q shielded inductor is used for implementation, the phase noise of the VCO improves tremendously (for example, by greater than 2×).

In one embodiment, an integrated circuit includes a voltage controlled oscillator as illustrated in FIG. 3 that is coupled to an electronic circuit. The VCO is implemented in a wireless communication system including an RF system, baseband clock generation circuit for high speed serial interfaces, and analog to digital converters. The integrated circuit includes a microprocessor. In one embodiment, the implementation of VCO of FIG. 3 was able to achieve phase noise for 20 GHz center frequency at −122 dBc/Hz at 1 MHz offset and at −100 dBc/Hz at 100 KHz offset. There is also approximately 15 dB improvement in phase noise when compared to the implementations of FIGS. 1 and 2.

In one embodiment, the center tapped inductor 310 and degeneration inductor 335 are implemented as illustrated in FIG. 5, 505 and 510 respectively. The center tapped inductor 505 and degeneration inductor 510 are implemented in different thick metals. Degeneration inductor 510 is thinner than center tapped inductor 505 to improve its self-resonance frequency since it needs to operate at twice the oscillation frequency. Both these inductors 505 and 510 have shield structures to improve the quality factor. They are interleaved at the ends in a symmetric manner and the cross coupled pair is placed slotted shield in the middle of the two inductors.

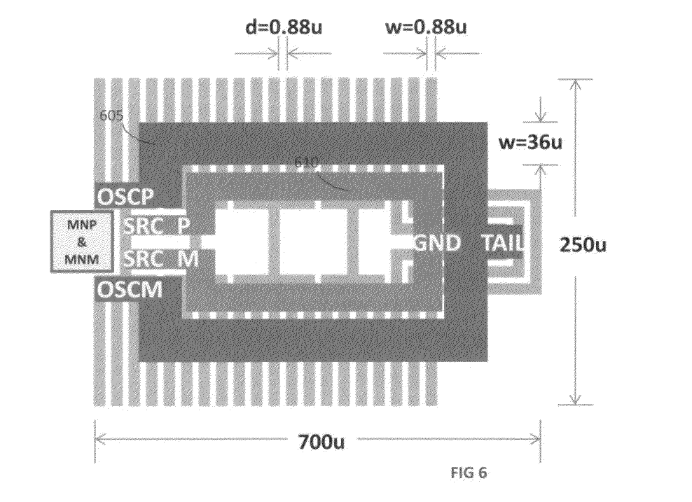

Another implementation of the center tapped inductor 310 and degeneration inductor 335 according to an embodiment is illustrated in FIG. 6, 605 and 610 respectively. The center tapped inductor 605 and the degeneration inductor 610 are implemented in different thick metals. Degeneration inductor 610 is thinner than the center tapped inductor 605 to improve its self-resonance frequency since it needs to operate at twice the oscillation frequency. The center tapped inductor 605 and degeneration inductor 610 are completely interleaved within one another and both these inductors have a common shield structure to improve the quality factor. This implementation while preserving the high quality factor reduces the area by 50% compared to the implementations in FIGS. 1 and 2.

The foregoing description sets forth numerous specific details to convey a thorough understanding of the invention. However, it will be apparent to one skilled in the art that the invention may be practiced without these specific details. Well-known features are sometimes not described in detail in order to avoid obscuring the invention. Other variations and embodiments are possible in light of above teachings, and it is thus intended that the scope of invention not be limited by this Detailed Description, but only by the following Claims.

What is claimed is:

1. A voltage controlled oscillator comprising:
an LC tank circuit coupled between a supply terminal, a first node and a second node;
a pair of cross coupled transistors coupled to the first node and the second node; and
a degeneration inductor, coupled to the pair of cross coupled transistors, configured to inductively degenerate each of the pair of cross coupled transistors and configured to resonate a source capacitance of each of the pair of cross coupled transistors at twice an oscillation frequency of the voltage controlled oscillator.

2. The voltage controlled oscillator of claim 1, wherein the LC tank circuit is coupled to the supply terminal through a resistor.

3. The voltage controlled oscillator of claim 1, wherein the LC tank circuit comprises a center tapped inductor coupled in parallel with a variable capacitor for providing inductance between the supply terminal and the first node and the supply terminal the second node, and for providing capacitance between the first node and the second node.

4. The voltage controlled oscillator of claim 3, wherein a pair of cross coupled transistors are cross coupled between a gate and a drain of each of the transistors, and the source terminals of each of the transistors are coupled to the degeneration inductor; and wherein the pair of cross coupled transistors are configured to compensate for the losses in the center tapped inductor and the variable capacitor.

5. The voltage controlled oscillator of claim 1, wherein the degeneration inductor is center tapped to a ground terminal.

6. The voltage controlled oscillator of claim 1, wherein the degeneration inductor is configured to linearize a gain of the pair of cross coupled transistors such that there is low flicker noise up-conversion at high oscillation swings in the voltage controlled oscillator.

7. The voltage controlled oscillator of claim 1, wherein the degeneration inductor is configured to minimize a Vgs of the cross coupled pair of transistors at crossover of a differential outputs of the voltage controlled oscillator.

8. The voltage controlled oscillator of claim 1, wherein the degeneration inductor is configured to provide a high impedance path to the ground terminal when any one of cross coupled pair transistors enters a triode region due to high oscillation swings thereby not degrading a quality factor of the LC tank circuit at high oscillation swings.

9. The voltage controlled oscillator of claim 3, wherein the degeneration inductor is thinner than the center tapped inductor to improve its self-resonance frequency.

10. The voltage controlled oscillator of claim 3, wherein the degeneration inductor and the center tapped inductor have shield structures to improve the quality factor.

11. The voltage controlled oscillator of claim 3, wherein the degeneration inductor and the center tapped inductor are implemented in different thick metals.

12. The voltage controlled oscillator of claim 3, wherein the center tapped inductor and the degeneration inductor are completely interleaved within one another and have a common shield structure to improve the quality factor.

13. An integrated circuit comprising:
a voltage controlled oscillator coupled to an electronic circuit, the voltage controlled oscillator comprising:
an LC tank circuit coupled between a supply terminal, a first node and a second node;
a pair of cross coupled transistors coupled to the first node and the second node; and
a degeneration inductor, coupled to the pair of cross coupled transistors, configured to inductively degenerate each of the pair of cross coupled transistors; and
configured to resonate a source capacitance of each of the pair of cross coupled transistors.

14. The integrated circuit of claim 13, wherein the electronic circuit comprises one of a radio frequency circuit, a baseband clock generation circuit for high speed serial interface, and an analog to digital converter; and wherein the integrated circuit comprises a microprocessor.
